(19) United States
(12) Patent Application Publication
(10) Pub. No.: US 2017/0256314 A1
(43) Pub. Date: Sep. 7, 2017

(54) RESISTIVE RANDOM ACCESS MEMORY AND WRITE OPERATION METHOD THEREOF

(71) Applicant: Fudan University, Shanghai (CN)

(72) Inventors: Yinyin LIN, Shanghai (CN); Jianguo YANG, Shanghai (CN)

(21) Appl. No.: 15/511,708

(22) PCT Filed: Jun. 12, 2015
(86) PCT No.: PCT/CN2015/081328

§ 371 Date: Mar. 16, 2017

(30) Foreign Application Priority Data
Sep. 16, 2014 (CN) 201410471864.1

(51) Int. Cl. G11C 13/00

(52) U.S. Cl. CPC G11C 13/0069

(57) ABSTRACT

The present invention relates to resistive random access memory (ReRAM). Disclosed are a ReRAM and write operation method thereof. The write operation method comprises monitoring, under a pre-operation signal bias, whether a conversion from a high resistance stage (HRS)/low resistance stage (LRS) to a LRS/HRS begins to occur, and controlling a change in a conversion operation signal, thus conducting a setting/resetting operation. The write operation method improves the storage performance of the ReRAM.

### a) FIELD OF THE INVENTION

The invention relates to the technical field of resistive random access memory (ReRAM), and relates to a write operation method which performs set/reset operations by monitoring a time point at which a high resistance state (HRS) to a low resistance state (LRS) conversion is initiated/at which a LRS to HRS conversion is initiated, as well as a ReRAM for realizing the write operation method.

### b) BACKGROUND

An extensive research has been made on ReRAM due to ReRAM's characteristics such as being non-volatile, having a low cost and a high density, and being able to break through restrictions of process technical generation development, etc, and ReRAM is considered as one of the semiconductor storage techniques that are likely to replace flash memory.

Each storage unit of ReRAM enables the storage medium to perform a reversible conversion between HRS and LRS by a biased electrical signal, thus realizing the storing function, wherein a conversion from HRS to LRS is typically defined as “set” operation, and a conversion from LRS to HRS is typically defined as “reset” operation. The set and reset operations constitute a write operation of ReRAM.

The paper “Atomic structure of conducting nanofilaments in TiO2 resistive switching memory” published on Nature Nanotechnology by Deok-Hwang Kwo, et al., demonstrates that during the set operation, the storage medium will form a plurality of conductive filaments (CFs) through movements of oxygen vacancies for example, thus realizing a low resistance conduction between a top electrode (TE) and a bottom electrode (BE) of the storage medium; moreover, during the reset operation, CFs are cut off or removed so as to realize a conversion to high resistance.

It is further found that when the write operation is performed using an electrical signal biased on the ReRAM, different forms of electrical signal can have an influence on the variation of CFs of the storage medium, thus affecting the storage performance of ReRAM, such as endurance, data retention and high resistance value/low resistance value window, etc. Therefore, the write operation is very important for the storage performance of memory.

US patent No. “U.S. Pat. No. 7,920,405B2”, entitled “CIRCUITS AND METHODS FOR ADAPTIVE WRITE BIAS DRIVING OF RESISTIVE NON-VOLATILE MEMORY DEVICES” filed by Sang-beom kang, et al., discloses a write operation method of ReRAM in which the write voltage is increased stepwise, and the set voltage of the write operation is shown in FIG. 1 which discloses a schematic view of the set operation signal of the ReRAM according to an embodiment of the prior art. In this patent, it is disclosed that a variation of the write voltage is dynamically fed back so as to determine whether the write operation is successful and to timely cut off the write voltage.

US patent publication No. “US2012/0075908A1”, entitled “RESISTIVE RANDOM ACCESS MEMORY AND VERIFYING METHOD THEREOF” filed by Chil-He Lin, et al., discloses another write operation method of ReRAM in which the write voltage pulse is increased stepwise, as shown in FIG. 2 which shows a schematic view of the set operation signal of the ReRAM according to another embodiment of the prior art. In this patent application, after each stage of the stepwise increased voltage pulse is biased, a verification operation is required so as to verify whether the write operation is successfully, and thereby to stop biasing the write voltage pulse.

### c) SUMMARY OF THE INVENTION

An object of the invention is to improve the storage performance of the ReRAM by changing the write operation process.

In order to achieve the above or other objects, the invention provides the following technical solutions.

According to an aspect of the invention, a resistive random access memory is provided, comprising:

a write operation signal generation module which is used for at least generating a pre-operation signal of a set/reset operation signal and a conversion operation signal whose voltage is decreased/increased gradually; and

a conversion initiation monitoring module for determining whether an initiation of a conversion from a high resistance state/low resistance state to the low resistance state/high resistance state has happened in a storage unit of the resistive random access memory biased with the pre-operation signal, and outputting a first feedback signal when the initiation of a conversion from a high resistance state/low resistance state to the low resistance state/high resistance state has happened;

wherein the write operation signal generation module generates the conversion operation signal based on the first feedback signal and biases the conversion operation signal onto the storage unit so as to keep performing a set/reset operation process from the high resistance state/low resistance state to the low resistance state/high resistance state.

In an embodiment, the conversion initiation monitoring module is further configured to monitor whether the set/reset operation is successful, and to output a second feedback signal when a successful set/reset operation is monitored; and

the write operation signal generation module terminates the generation of the conversion operation signal based on the second feedback signal.

According to another aspect of the invention, a write operation method of resistive random access memory is provided, comprising the following steps during a set/reset operation process:

biasing a pre-operation signal of a set/reset operation signal onto a storage unit of the resistive random access memory;

determining whether an initiation of a conversion from a high resistance state/low resistance state to the low resistance state/high resistance state has happened, and outputting a first feedback signal if it is determined “yes”; and

generating a conversion operation signal whose voltage is decreased/increased gradually based on the first feedback signal, and biasing the conversion operation signal onto the storage unit so as to keep performing a set/reset operation process from the high resistance state/low resistance state to the low resistance state/high resistance state.

In an embodiment, when the reset operation process is continued, whether the reset operation is successfully is determined, and a second feedback signal is output so as to terminate the reset operation when it is determined that the reset operation is successfully.

According to further another aspect of the invention, a resistive random access memory is provided, comprising:

a write operation signal generation module which is used for at least generating a pre-operation signal whose voltage is increased gradually of a reset operation signal, and a conversion operation signal of the reset operation signal; and

a conversion initiation monitoring module for determining whether an initiation of a conversion from a low resistance state to a high resistance state has happened in a storage unit of the resistive random access memory biased with the pre-operation signal, and outputting a first feedback signal when the initiation of a conversion from a low resistance state to the high resistance state has happened;

wherein the write operation signal generation module terminates an increasing process of the pre-operation signal based on the first feedback signal and substantially maintains the output electrical level so as to generate the conversion operation signal, and biases the conversion operation signal onto the storage unit so as to keep performing the reset operation process from the low resistance state to the high resistance state.

According to still another aspect of the invention, a write operation method of resistive random access memory is provided, comprising the following steps during a reset operation process:

biasing a pre-operation signal of a reset operation signal onto a storage unit of the resistive random access memory, wherein the voltage of the pre-operation signal is increased gradually;

determining whether an initiation of a conversion from a low resistance state to a high resistance state has happened, and outputting a first feedback signal if it is determined “yes”; and

terminating an increasing process of the pre-operation signal based on the first feedback signal and substantially maintaining the output electrical level so as to generate the conversion operation signal, and biasing the conversion operation signal onto the storage unit so as to keep performing the reset operation process from the low resistance state to the high resistance state.

### d) BRIEF DESCRIPTION OF THE DRAWINGS

The above and other objects and advantages of the invention will become more complete and clear from the above detailed description with reference to the accompanying drawings, wherein identical or similar elements are denoted by identical reference signs.

FIG. 1 is a schematic view of a set operation signal of the ReRAM according to an embodiment of the prior art.

FIG. 2 is a schematic view of a set operation signal of the ReRAM according to another embodiment of the prior art.

FIG. 3 is a schematic view of the structure of modules of the ReRAM according to an embodiment of the invention.

FIG. 4 is a schematic view of a set operation signal according to an embodiment of the invention.

FIG. 5 is a schematic view of a reset operation signal according to an embodiment of the invention.

FIG. 6 is a schematic view of a reset operation signal according to another embodiment of the invention.

FIG. 7 is a schematic view of the structure of modules of an example of a conversion initiation monitoring module among the modules of the ReRAM according to the embodiment shown in FIG. 3 of the invention.

FIG. 8 is a schematic view of the structure of modules of another example of a conversion initiation monitoring module among the modules of the ReRAM according to the embodiment shown in FIG. 3 of the invention.

FIG. 9 is a schematic view of the flowchart of the method of set operation according to an embodiment of the invention.

FIG. 10 is a schematic view showing the formation of conductive filaments in the ReRAM.

FIG. 11 is a schematic view of the flowchart of the method of reset operation according to an embodiment of the invention.

FIG. 12 is a schematic view of the flowchart of the method of reset operation according to another embodiment of the invention.

### e) DETAILED DESCRIPTION OF THE INVENTION

Some of a plurality of embodiments of the invention will be described below with the purpose of providing a basic understanding of the invention rather than identifying key elements or crucial elements of the invention or limiting the scope of protection. It can be easily understood that according to the technical solution of the invention, those skilled in the art can propose other implementations that can be replaced with each other without departing from the true spirit of the invention. Therefore, the following specific embodiments and drawings are merely exemplary description of the technical solutions of the invention, and should not be considered as the entirety of the invention or as limiting or restricting the technical solutions of the invention.

For a clear and brief explanation, in the following description, not all the components shown in the accompanying drawings are described in detail. The drawings show many components that can be completely realized for completing the invention by those skilled in the art. For those skilled in the art, the operations of many components are familiar and obvious

In the following, a high resistance state of the storage unit in the ReRAM is defined as data “0”, and correspondingly, a low resistance state of the storage unit is defined as data “1”; a set operation is a write operation which writes data “0” to be data “1”, i.e., a write “1” operation, and a reset operation is a write operation which writes data “1” to be data “0”, i.e., a write “0” operation.

The applicant notes that during a resistance conversion process in the storage unit of the ReRAM, the conversion speed of resistance states is very fast, and a variation in operation voltage mainly originates before conversion of resistance states. Existing dynamic feedback write paths (such as the technical solution disclosed in U.S. Pat. No. 7,920,405B2) mainly adds a real time current detection module into the write path, and a write voltage signal V_{write} is enabled to be cut-off only when set/reset is completed. In this way, although excessive write voltage signals V_{write} (e.g., voltage pulses) can be prevented from being applied to the storage unit to cause harm to the storage performance of the storage unit of ReRAM, the applicant finds that the storage performance of the storage unit of ReRAM will still be damaged to some extent in case that the write voltage signal Vwrite is cut off after set/reset is completed, since the resistance conversion process of ReRAM is very fast. For example, there will be problems such as deterioration of consistency of resistances at high resistance state and/or low resistance state (in a more discrete distribution), reduction of high/low resistance window R_{off}/Rₒₙ, etc. These problems will significantly affect and restrict actual applications of ReRAM.

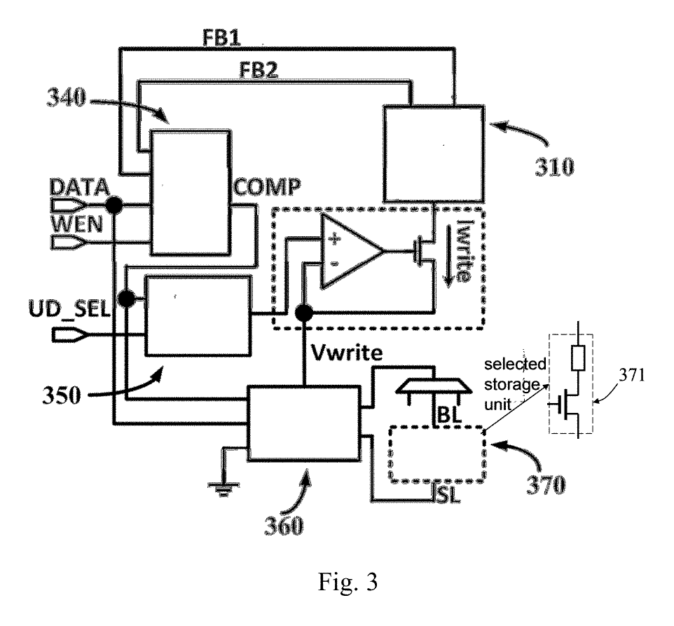

FIG. 3 is a schematic view of the structure of modules of the ReRAM according to an embodiment of the invention. As shown in FIG. 3, the ReRAM also comprises a plurality of storage units, each of which can realize a back and forth conversion between a high resistance state (HRS) and a low resistance state (LRS); a plurality of storage units can form a memory array 370 in rows and columns. In this embodiment of the invention, in order for a concise and clear description, only the set/reset operation process when one storage unit 371 of the memory array 370 is selected is described by way of example. Herein, in order to facilitate understanding, the electrical signals biased on the storage unit 371 is considered as being all applied to the storage resistor of the storage unit, that is, a voltage dividing effect on the storage resistor caused by a selecting transistor of the storage unit or the like is substantially omitted (the resistance is omitted when the selecting transistor is in an on-state). Specifically, the ReRAM comprises a selector which selects a corresponding storage unit from the memory array 370 according to an address signal, e.g., a column selector, wherein BL represents a bit line in the memory array, and SL represent a source line in the memory array.

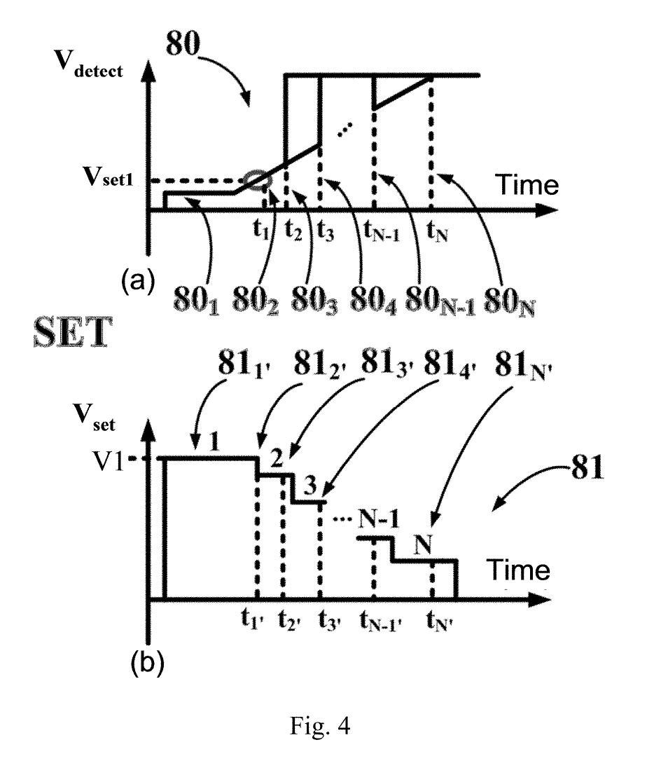

In this embodiment, the ReRAM is further provided with a write operation signal generation module 350 which can generate a set operation signal and/or a reset operation signal, the specific forms of which will be described in detail below with reference to FIGS. 4 to 6.

In this embodiment, the ReRAM is further provided with a conversion initiation monitoring module 310 which determines whether an initiation of conversion from HRS to LRS (when the set operation is executed) has happened in the selected storage unit 371 of the memory, or determines whether an initiation of conversion from LRS to HRS (when the reset operation is executed) has happened in the storage unit 371 of the memory by monitoring a variation of the electrical signal biased on the selected storage unit 371. Herein, the time point at which the initiation of conversion from LRS to HRS happens or the time point at which the initiation of conversion from HRS to LRS happens is defined as “time point of resistance state conversion”. It should be understood that this time point is a single time point or a small piece of time points in the fast resistance state conversion process of storage unit and the “time point” is not limited to a very tiny point of moment. It is defined with respect to the “resistance conversion process”, and can be a “resistance conversion initiation process” of the “resistance conversion process”. Those skilled in the art will understand that, before the resistance conversion process of ReRAM happens, the resistance of the storage unit 371 is substantially not changed. Under the action of the biased electrical signal, if the conductive filaments in the storage medium of the storage unit has changed (e.g., begin to form or begin to break), it means that the resistance of the storage unit begins to change. Specifically, the rate of change of the current flowing through the storage unit is obviously accelerated as compared to before, or the voltage detected on the storage unit changes to a predefined value. It should be understood that in case that the biased excited voltage is substantially not changed, the variation of voltage on the storage unit is caused by variation of the current flowing through the storage unit. The variation of the current flowing through the storage unit or the variation of voltage detected on the storage unit is one of the forms that reflect resistance change of the storage unit.

In this embodiment, the conversion initiation monitoring module 310 can further has a function of determining whether the write operation is successfully. Specifically, when the conversion initiation monitoring module 310 monitors an “initiation point” of resistance state conversion, i.e., when an initiation of conversion from HRS to LRS or an initiation of conversion from LRS to HRS happens, a signal FB1 is output to a logic control module 340 so as to further control the variation of signal of the set operation or the reset operation (the specific form of variation will be described below in subsequent embodiments) based on the feedback signal FB1, thereby keeping biasing the conversion operation signal of the set operation or the reset operation signal onto the storage unit 371 and completing the set operation or reset operation process; when the conversion initiation monitoring module 310 monitors that the set operation or the reset operation is successful, it outputs a signal FB2 to the logic control module 340 so as to further control the variation of signal of the set operation or the reset operation based on the feedback signal FB2.

In the above embodiment, “monitoring” can be realized by dynamically detecting the voltage or the current.

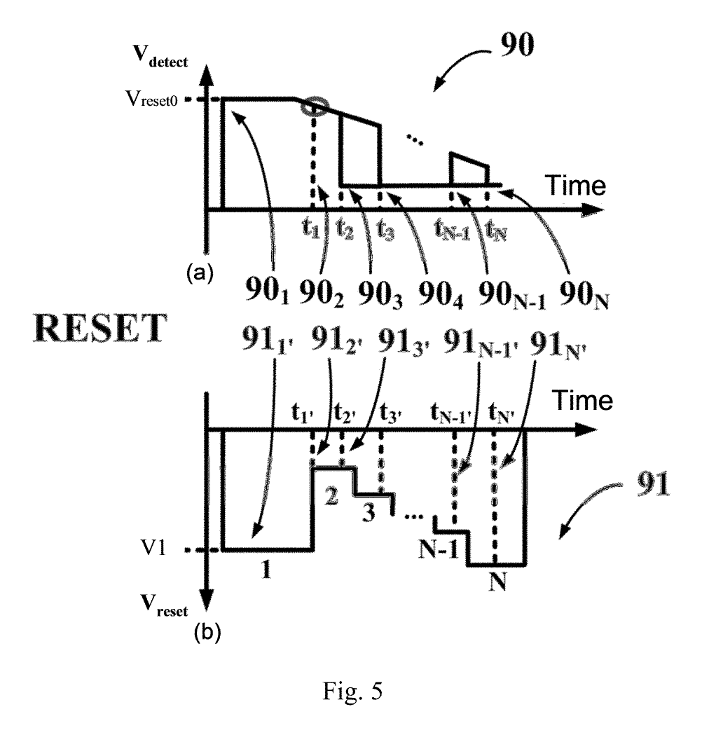

With continued reference to FIG. 3, an input end of the logic control module 340 accesses data signal DATA, i.e., data signal that needs to be written-in. If DATA=0, it means that the reset operation is required; and if DATA=1, it means that the set operation is required. The input end of the logic control module 340 further accesses a write enabling signal WEN. In this example when WEN=1, a write path is enabled to work, and the set or reset operation is initiated. An output end of the logic control module 340 is coupled with a write operation signal generation module 350 and a polarity selector 360 which is used for controlling the polarity of the set/reset operation signal biased onto the storage unit 371. For example, when DATA=1, the write voltage (V_{write}) generated by the write operation signal generation module 350 is biased onto the storage unit 371 from the BL direction, which is the direction of set operation; on the contrary, V_{write} is biased onto the storage unit 371 from the SL direction so as to perform reset operation. The logic control module 340 can further enable the polarity selector 360 to stop working based on the signal FB2. It is noted that in the invention, the polarities of the set operation signal and the reset operation signal are not limiting, they can either be unipolar, or be bipolar as shown below in FIGS. 4 and 5.

With continued reference to FIG. 3, the signal generated by the write operation signal generation module 350 is input to a “+” input end (positive input end) of an amplifier, and a “−” input end (negative input end) of the amplifier is connected to the polarity selector 360. For an ideal operational amplifier, the voltage on the positive input end is completely the same as the voltage on the negative input end. The operational amplifier and a transistor connected to the output end thereof form a negative feedback loop circuit, thus forming a write voltage-current converter.

Of the signals generated by the write operation signal generation module 350, the voltage of the set operation signal is decreased gradually, and the voltage of the reset operation signal is increased gradually. The set operation signal and the reset operation signal generated by the write operation signal generation module 350 will be described in detail below.

FIG. 4 is a schematic view of a set operation signal according to an embodiment of the invention. As shown in FIG. 4, FIG. 4(b) shows a biased set operation signal 81 which is generated by the write operation signal generation module 350, and FIG. 4(a) shows a voltage waveform signal 80 of the set operation detected in a write path when the set operation signal 81 shown in FIG. 4(b) is biased onto the storage unit. In FIGS. 4(a) and 4(b), moment t_{1′} corresponds to moment t₁, moment t_{2′} corresponds to moment t₂, moment t_{3′} corresponds to moment t₃, moment t_{N-1′} corresponds to moment t_{N-1}, and moment t_{N′} corresponds to moment t_{N}. In this embodiment, the set operation signal 81 comprises a pre-operation signal portion and a conversion operation signal portion; the voltage of the conversion operation signal portion is decreased gradually; specifically, it is decreased in continuous steps, which may include (N−1) steps, wherein N is an integer larger than or equal to 2.

81_{1′} represents a voltage waveform applied before a conversion from HRS to LRS happens in the storage unit 371 (i.e., before the moment t_{1′}), i.e., the corresponding pre-operation signal in the invention, which can be a fixed voltage value V1. In other embodiments, in order to shorten the time period before the conversion from HRS to LRS happens, i.e., to shorten the time before t_{1′}, the voltage value of the pre-operation signal 81_{1′} can be also increased gradually.

81_{2′} to 81_{N′} represent the 2^{nd} to the N^{th} voltage steps of set operation signal 81 which is decreased in continuous steps, and they form the conversion operation signal of the set operation signal 81; moment t_{2′} to moment t_{N′} represent any of the voltage steps after moment t_{1′}, at any moment of which a successful set operation can be realized; one of moment t_{2′} to moment t_{N′} represents a successful set operation may happen, and accordingly, the biased set operation signal 81 is cut off at this moment, i.e., is terminated.

Correspondingly, the voltage waveform signal 80 of the set operation detected by the write path also varies with the variation of the set operation signal 81 and the variation of the resistance state of the storage unit 371. Since the variation of the set operation signal 81 has only little influence on the variation of the voltage waveform signal 80 of the set operation, the variation of the set operation signal 81 is not particularly taken into consideration herein, wherein 80₁ represents the voltage detected when the pre-operation signal 81_{1′} is biased, the voltage of the signal 80₁ corresponding to moment t₁ begins to decrease, and this is the voltage signal detected when the initiation of conversion from LRS to HRS happens; 80₂ to 80_{N} respectively represent the voltage detected when the set operation is successful in case that any of the conversion operation signals 81_{2′} to 81_{N′} is biased. In this embodiment, 80₂ to 80_{N} are in the form of abrupt edges of the voltage.

In this embodiment, the voltage V1 of the pre-operation signal 81_{1′} can be selected within a certain range. Typically, V1 can be selected to be smaller than a voltage value at which a single pulse enables a successful set operation, or to be smaller than a voltage corresponding to the set conversion point in case of voltage scanning test, i.e., a set voltage. Those skilled in the art can determine the magnitude of V1 according to set tests performed on a plurality of storage units. It should be understood that the specific magnitude of Vₛₑₜ is not limited to the embodiments of the invention.

The conversion operation signal begins to decrease stepwise from V1, and the amplitude of stepwise decreased voltage between voltage steps 81_{2′} to 81_{N′} is not limiting. In order to improve the efficiency of set operation, limits can be set for N and the magnitude of the voltage of the voltage step 81_{N′} so as to prevent excessive time from being consumed when the set operation was not successful in a certain storage unit.

At each voltage step as shown above in FIG. 4, it is possible to realize a successful set operation. As described above, with the conversion initiation monitoring module 310 monitoring I_{write} dynamically, the time point t₂, t₃ . . . or t_{N} of successful set operations can be determined, and the set operation signal 81 can be terminated at corresponding time point t_{2′}, t_{3′}. . . or t_{N′}.

FIG. 5 is a schematic view of a reset operation signal according to an embodiment of the invention. As shown in FIG. 5, FIG. 5(b) shows a biased reset operation signal 91 which is generated by the write operation signal generation module 350, and FIG. 5(a) shows a voltage waveform signal 90 of the reset operation detected in a write path when the reset operation signal 91 shown in FIG. 5(b) is biased onto the storage unit. In FIGS. 5(a) and 5(b), moment t_{1′} corresponds to moment t₁, moment t_{2′} corresponds to moment t₂, moment t_{3′} corresponds to moment t₃, moment t_{N-1′} corresponds to moment t_{N-1}, and moment t_{N′} corresponds to moment t_{N}. In this embodiment, the reset operation signal 91 comprises a pre-operation signal portion and a conversion operation signal portion; the voltage of the conversion operation signal portion is increased gradually; specifically, it is increased in continuous steps, which may include (N−1) steps, wherein N is an integer larger than or equal to 2.

91_{1′} represents a voltage waveform applied before a conversion from LRS to HRS happens in the storage unit 371 (i.e., before the moment t_{1′}), i.e., the corresponding pre-operation signal in the invention, which can be a fixed voltage value V1. In other embodiments, in order to shorten the time period before the conversion from LRS to HRS happens, i.e., to shorten the time before t_{1′}, the voltage value of the pre-operation signal 91_{1′} can be also increased gradually.

91_{2′} to 91_{N′} represent the 2^{nd} to the N^{th} voltage steps of reset operation signal 91 which is increased in continuous steps, and they form the conversion operation signal of the reset operation signal 91; moment t_{2′} to moment t_{N′} represent any of the voltage steps after moment t_{1′}, at any moment of which a successful reset operation can be realized; one of moment t_{2′} to moment t_{N′} represents a successful reset operation may happen, and accordingly, the biased reset operation signal 91 is cut off at this moment, i.e., is terminated.

Correspondingly, the voltage waveform signal 90 of the reset operation detected by the write path also varies with the variation of the reset operation signal 91 and the variation of the resistance state of the storage unit 371. Since the variation of the reset operation signal 91 has only little influence on the variation of the voltage waveform signal 90 of the reset operation, the variation of the reset operation signal 91 is not particularly taken into consideration herein, wherein 90₁ represents the voltage detected when the pre-operation signal 91_{1′} is biased, the voltage of the signal 90₁ corresponding to moment t₁ begins to decrease, and this is the voltage signal detected when the initiation of conversion from LRS to HRS happens; 90₂ to 90_{N} respectively represent the voltage detected when the reset operation is successful in case that any of the conversion operation signals 91_{2′} to 91_{N′} is biased. In this embodiment, 90₂ to 90_{N} are in the form of abrupt edges of the voltage.

In this embodiment, the voltage V1 of the pre-operation signal 91_{1′} can be selected within a certain range. Typically, V1 can be selected to be smaller than a voltage value at which a single pulse enables a successful reset operation, or to be smaller than a voltage corresponding to the reset conversion point in case of voltage scanning test, i.e., a reset voltage. Those skilled in the art can determine the magnitude of V1 according to reset tests performed on a plurality of storage units. It should be understood that the specific magnitude of V₁ is not limited to the embodiments of the invention.

The initial voltage of the conversion operation signal is smaller than V1, that is, the voltage of voltage step 91_{2′} is smaller than V1. Therefore, at moment t_{1′}, the relatively higher voltage V1 of the pre-operation signal is decreased to the initial voltage, and the magnitude of this reduction is not limiting. The amplitude of stepwise increased voltage between voltage steps 91_{2′} to 91_{N′} is also not limiting. In order to improve the efficiency of reset operation, limits can be set for N and the magnitude of the voltage of the voltage step 91_{N′} so as to prevent excessive time from being consumed when the reset operation was not successful in a certain storage unit.

At each voltage step as shown above in FIG. 5, it is possible to realize a successful reset operation. As described above, with the conversion initiation monitoring module 310 monitoring I_{write} dynamically, the time point t₂, t₃ . . . or t_{N} of successful reset operations can be determined, and the reset operation signal 91 can be terminated at corresponding time point t_{2′}, t_{3′}. . . or t_{N′}.

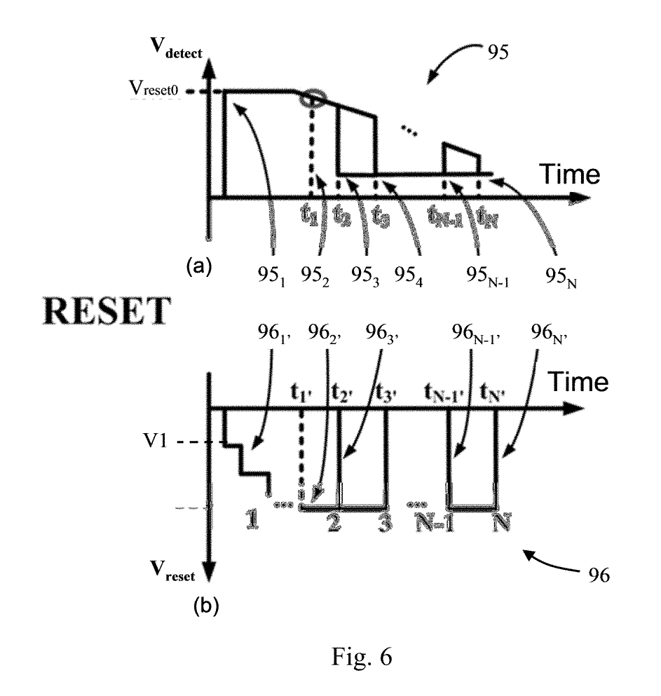

FIG. 6 is a schematic view of a reset operation signal according to another embodiment of the invention. As shown in FIG. 6, FIG. 6(b) shows a biased reset operation signal 96 which is generated by the write operation signal generation module 350, and FIG. 6(a) shows a voltage waveform signal 95 of the reset operation detected by a write path when the reset operation signal 96 shown in FIG. 6(b) is biased onto the storage unit. In FIGS. 6(a) and 6(b), moment t_{1′} corresponds to moment t₁, moment t_{2′} corresponds to moment t₂, moment t_{3′} corresponds to moment t₃, moment t_{N-1′} corresponds to moment t_{N-1}, and moment t_{N′} corresponds to moment t_{N}.

96_{1′} represents a voltage waveform applied before a conversion from LRS to HRS happens in the storage unit 371 (i.e., before the moment t_{1′}), i.e., the corresponding pre-operation signal in the invention. The voltage of the pre-operation signal 96_{1′} is increased gradually; specifically, it is increased in continuous steps, and the number of the steps is not limiting. The magnitude of the continuously stepwise increased initial voltage V1 of the pre-operation signal is relatively small and is much smaller than a voltage value at which a single pulse enables a successful reset operation, or to be smaller than a voltage corresponding to the reset conversion point in case of voltage scanning test, i.e., a reset voltage. Moment t_{1′} represents an initiation of the conversion from LRR to HRS happens, at which point the pre-operation signal 96_{1′} terminates the stepwise increasing process and maintains the output electrical level, that is, the conversion operation signal (i.e., one of the signals 96_{2′} to 96_{N′}) is generated,

96_{2′} to 96_{N′} are signals for continuing the reset operation, and the electrical levels thereof are substantially fixed at a certain valve. That is, the magnitudes of the electrical levels of signals 96_{2′}, 96_{3′}, . . . or 96_{N′} are equal to the highest electrical level of the pre-operation signal 96_{1′} and are output continuously. Moment t_{2′} to moment t_{N′} represent a successful reset operation can be realized at any moment after moment t_{2′}; one of moment t_{2′} to moment t_{N′} represents a successful reset operation may happen, and accordingly, the biased reset operation signal 96 is cut off at this moment, i.e., is terminated.

Correspondingly, the voltage waveform signal 95 of the reset operation detected by the write path also varies with the variation of the reset operation signal 96 and the variation of the resistance state of the storage unit 371. Since the variation of the reset operation signal 96 has only little influence on the variation of the voltage waveform signal 95 of the reset operation, the variation of the reset operation signal 96 is not particularly taken into consideration herein, wherein 95₁ represents the voltage detected when the pre-operation signal 96_{1′} is biased, the voltage of the signal 96₁ corresponding to moment t₁ begins to decrease, and this is the voltage signal detected when the initiation of conversion from LRS to HRS happens; 95₂ to 95_{N} respectively represent the voltage detected when the reset operation is successful corresponding to any of the conversion operation signals 96_{2′} to 96_{N′}. In this embodiment, 95₂ to 95_{N} are in the form of abrupt edges of the voltage.

In this embodiment, the voltage V1 of the pre-operation signal 96_{1′} at moment t₁ is typically smaller than a voltage value at which a single pulse enables a successful reset operation, i.e., a reset voltage.

The reset operation signal in the stage of maintaining the electrical level as shown in FIG. 6 make it possible to realize a successful reset operation. As described above, with the conversion initiation monitoring module 310 monitoring I_{write} dynamically, the time point t₂, t₃ . . . or t_{N} of successful reset operations can be determined, and the reset operation signal 96 can be terminated at corresponding time point t_{2′}, t_{3′}. . . or t_{N′}.

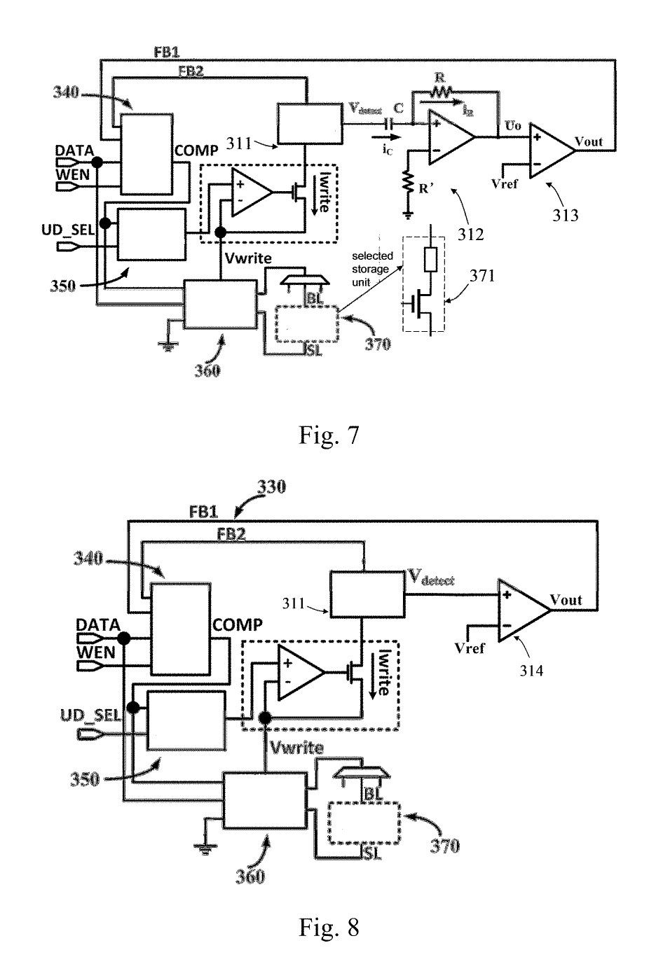

FIG. 7 is a schematic view of the structure of modules of an example of a conversion initiation monitoring module among the modules of the ReRAM according to the embodiment shown in FIG. 3 of the invention. In this embodiment, the conversion initiation monitoring module 310 comprises a write path current detector 311, a differentiating circuit 312 and a comparator 313, and the differentiating circuit 312 and the comparator 313 constitute a specific example of edge detection circuit, wherein the write path current detector 311 is used for dynamically detecting a write current I_{write} in the write path when a write excitation (signals 81, 91 or 96 as shown in FIGS. 4 to 6) is biased onto the selected storage unit 371, and can output signals 80, 90 or 95 as shown in FIGS. 4 to 6; the operational principle of the differentiating circuit 312 is expressed by the following equation (1):

$$Uo = - {i}_{R} R = - RC \frac{{du}_{1}}{dt} \qquad ( 1 )$$

wherein U₀ is the output voltage signal of the differentiating circuit 312.

When the resistance state of the storage unit 371 begins to change, there is a significant variation in the voltage of V_{detect} of signals 80, 90 or 95 as compared to before. At this point, the differentiating circuit 312 can be used to detect a slope of voltage variation of V_{detect} of signals 80, 90 or 95, and the comparator 313 can be further used to determine whether an initiation of conversion from HRS to LRS or from LRS to HRS has happened, i.e., to determine moment t1, thereby feeding back an output signal FB1.

In this embodiment, the write current I_{write} monitored by the write path current detector 311 can be also used to determine whether the write operation (e.g., the set operation or the reset operation) is successful. The write path current detector 311 is coupled with the logic control module 340, and in case that the write path current detector 311 determines the write operation is successful, a feedback signal FB2 is sent to the logic control module 340 which, based on this signal FB2, enables the write operation signal generation module 350 to stop generating the set/reset operation signals (any of moments t_{2′} to t_{N′} as shown in FIGS. 4, 5 and 6). In this way, through a dynamic feedback from current detection, excessive set/reset excitations are prevented from being biased onto the storage unit on which a set/reset operation has been successfully performed, which is not only advantageous for improving the speed of set/reset operation, but also is advantageous for reducing power consumption of set/reset operation and improving data retention and consistency of resistance state values, etc.

In another embodiment, the variation of V_{detect} when the ser operation or the reset operation is successful can be detected by an edge detection circuit. For example, the differentiating circuit 312 and the comparator 313 detect descending or ascending edges of moments t₂, t₃ . . . or t_{N} as shown in FIGS. 4, 5 and 6, and thereby output the feedback signal FB2 to the logic control module 340.

FIG. 8 is a schematic view of the structure of modules of another example of a conversion initiation monitoring module among the modules of the ReRAM according to the embodiment shown in FIG. 3 of the invention. In this embodiment, the conversion initiation monitoring module 310 comprises a write path current detector 311 and a comparator 314, wherein the write path current detector 311 is used for dynamically detecting a write current I_{write} in the write path when a write excitation (signals 81, 91 or 96 as shown in FIGS. 4 to 6) is biased onto the selected storage unit 371, and can output monitored voltage V_{detect} as shown in FIG. 4(a), 5(a) or 6(a); the comparator 314 compares V_{detect} of signals 80, 90 or 95 with a predefined value V_{ref} and determines whether an initiation of conversion from HRS to LRS or from LRS to HRS has happened, or determines whether the set or reset operation has been successfully performed. The magnitude of V_{ref} can be selected differently according to different types of determination; when it is to determine whether an initiation of conversion from HRS to LRS has happened, V_{ref} represents a voltage detected when the conversion from HRS to LRS is initiated, and the value thereof is much smaller than that of a voltage detected after the set operation is successful and is larger than a voltage detected before the conversion from HRS to LRS is initiated; and when it is to determine whether an initiation of conversion from LRS to HRS has happened, V_{ref} represents a voltage detected when the conversion from LRS to HRS is initiated, and the value thereof is much larger than that of a voltage detected after the reset operation is successful and is smaller than a voltage detected before the conversion from LRS to HRS is initiated. V_{ref} can be obtained through many times of tests.

The set/reset operation method of the ReRAM according to an embodiment of the invention will be further disclosed hereinafter. The operation method can be used to explain the operational principle of ReRAM.

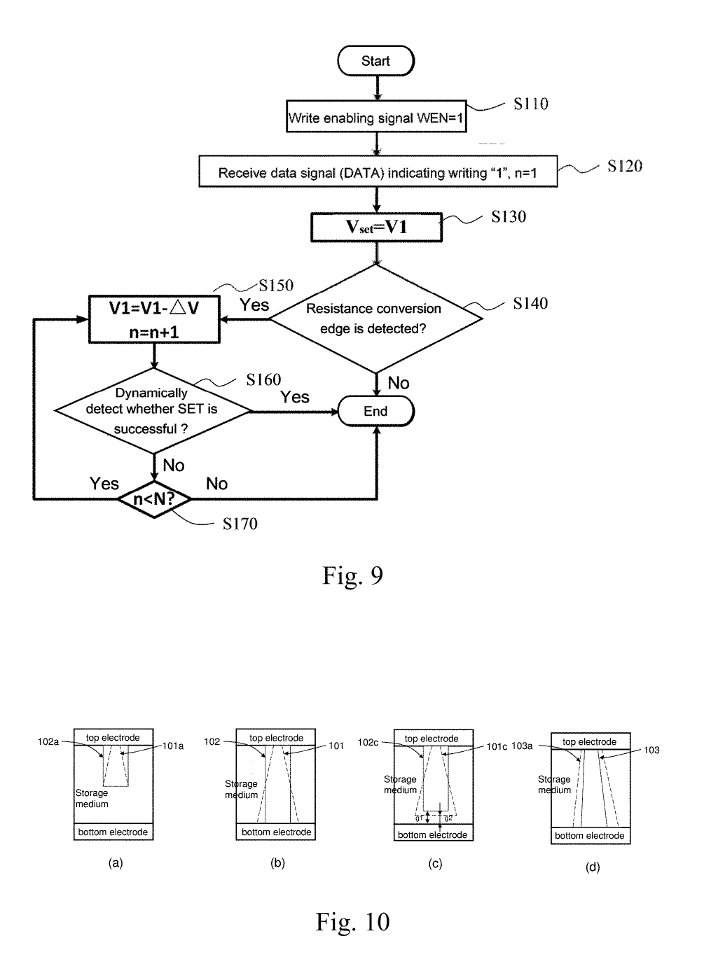

FIG. 9 is a schematic view of the flowchart of the method of set operation according to an embodiment of the invention. The process of set operation method will be described below in detail based on the set operation signal of the embodiment shown in FIGS. 9, 3 and 4.

Firstly, at step S110, the write enabling signal WEN is set at “1”, meaning that the write operation circuit is ready to initiate the write operation.

Next, at step S120, data signal (DATA) indicating writing DATA=1 is received, meaning that the set operation is required to be performed at this point, and meanwhile, n is set at 1. At this point, the logic control module 340 enables the write operation signal generation module 350 to generate the set operation signal 81 (including the pre-operation signal) as shown in FIG. 4 based on the DATA signal so as to exert excitation on the storage unit 371.

Next, at step S130, Vₛₑₜ=V1, that is, the pre-operation signal 81_{1′} of the set operation signal is applied to the storage unit 371, and the magnitude of the voltage of the pre-operation signal 81_{1′} is V1. At this step, DATA=1 simultaneously acts on the polarity selection module 360, and when DATA=1, the write operation voltage V_{write} is applied to the storage unit 371 in the BL direction.

Next, at step S140, whether an initiation of conversion from HRB to LRS is monitored. In an example, when the dynamically detected I_{write} is larger than a certain predefined value Iₛₑₜ₁ (Iₛₑₜ₁ is smaller than the current after the set operation is successfully performed on the storage unit), it means that at this point, an initiation of resistance state conversion is happening in the storage unit 371, that is, a conversion from HRS to LRS begins, and the output signal FB1 is fed back. In another example, specifically, whether the resistance conversion edge is dynamically detected can be determined by an edge detection circuit. That is, as shown in FIG. 9, when the dynamically detected I_{write} is changed (I_{write} become somewhat larger in the set process), it means that an initiation of state conversion is happening in the storage unit 371, that is, a conversion from HRS to LRS begins, the edge detection circuit detects an ascending edge of the voltage, and the output signal FB1 is fed back.

If an initiation of conversion from HRS to LRS is never monitored, it means that the storage unit has failed, and the set process is ended.

Next, at step S150, the set signal is decreased stepwise. For example, the pre-operation signal 81_{1′} is decreased stepwise to form a signal 81_{2′}. The signal 81_{2′} is used to keep performing the set operation process of conversion from HRS to LRS on the storage unit. The amplitude ΔV of stepwise decreasing is not limiting, and can for example be 0.1V.

At step S160, whether the set operation is successful is dynamically detected. Specifically, when the dynamically detected I_{write} is larger than a certain predefined value Iₛₑₜ₂ (Iₛₑₜ₂ is the current value in the write path after the operation on the storage unit is successful), it means that the set operation is successfully performed on the storage unit 371, and the feedback signal FB2 is valid; thereby, the logic control module 340 controls the write operation signal generation module 350 to cut off subsequent set operation signal, and the set operation signal is terminated, thus ending the set process. If no I_{write} larger than the certain predefined value Iₛₑₜ₂ has been detected, the voltage of the set operation signal is further decreased, that is, steps S170 and S150 are executed, wherein N in step S170 represents the maximum times of stepwise decreasing of the set operation signal. If n≧N, then it may be difficult to successfully perform the set operation on the storage unit, and the generation of set operation signal is terminated, thus ending the set operation process.

The above steps S150, S160 and S170 are executed repeatedly for several times so as to form the conversion operation signal of the continuously stepwise decreased set operation signal. The continuously stepwise decreased S conversion operation signal is biased on the storage unit 371 until the set operation is successful, and the generation of set operation signal is immediately terminated, thus avoiding excessive write excitation signals after the set operation is successful. In this way, the CFs formed by the set operation will not be affected by the write excitation signal such as the set operation signal anymore, which is advantageous for reducing additional power consumption. For example, as compared to existing set operations, the power consumption of set operation can be reduced by up to 34%; moreover, a destructive influence on the storage performance caused by an over-write operation can be also prevented. In addition, a conventional verifying operation may be not necessary, and the continuously stepwise decreased set operation signal is also more efficient than the set operation signal as shown in FIG. 2.

The technical effects brought about by the continuously stepwise decreased set operation signal and the principle thereof will be explained below in detail.

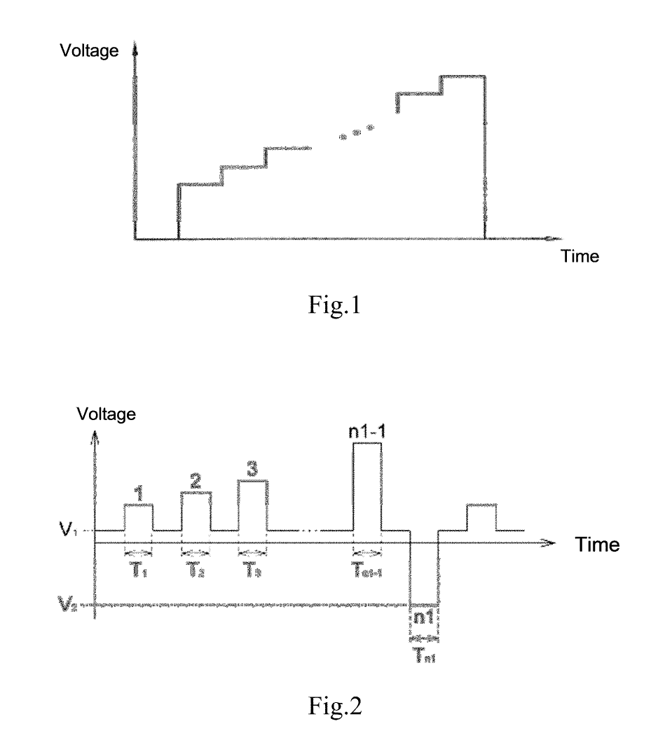

The applicant has conducted set operation tests on the same one ReRAM chip based on the set operation signal shown in FIG. 1 and the set operation signal shown in FIG. 4 respectively. A statistical analysis test result shows that the set operation signal of the invention whose voltage is gradually decreased can improve the storage performance at least from the following several aspects when compared with the conventional set operation signals whose voltages are gradually increased: (I) the endurance of the memory can be improved by at least two orders of magnitude; (II) the data retention of the memory is also improved, wherein the failure rate of data retention is reduced by at least 88% in an on-state Rₒₙ, and is reduced by at least 71% in an off-state R_{off}; and (III) the R_{off}/Rₒₙ window (i.e., high resistance window/low resistance window can be also increased by 7 times.

Of course, it should be understood that different types of ReRAM chip test units and other different test conditions or the like can also result in different results, that is, the extents to which the above aspects can be improved in terms of storage performance will be different.

The applicant also finds that by controlling the set operation signal to excite the storage unit using decreased voltage waveforms, the migration of oxygen vacancies for forming CFs in the storage medium can be controlled, thus controlling the shape of CFs and realizing improvements on the above described several aspects. Hereinafter, FIG. 10 exemplifies the formation of CFs and the reason why the storage performance of the ReRAM according to the embodiment of the invention can be improved by using the set operation signal whose voltage is stepwise decreased.

FIG. 10 is a schematic view showing the formation of conductive filaments in the ReRAM, wherein FIG. 10(a) is a schematic view before the CF is formed, FIG. 10(b) is a schematic view showing the shape of CF when the set operation is completed, FIG. 10(c) is a schematic view showing the shape of CF when the reset operation is completed, and FIG. 10(d) is a schematic view showing the influence on CF by an over-write operation. In FIGS. 10(a) to 10(c), the CF schematically shown by solid lines is formed based on the set operation method shown in FIG. 9, and the CF schematically shown by dashed lines is formed based on the set operation method shown in FIG. 1; in FIG. 10(d), 103 indicates CF that is not affected by over-set operation, and 103a indicates CF that is affected by over-set operation.

As shown in FIG. 10(a), CF is formed by movement of oxygen vacancies and oxygen ions under the action of set voltage. CF101a, 101 and 101c indicated by dashed lines are formed when the set excitation is a stepwise increased voltage. When the first step of stepwise voltage is applied to the storage unit of ReRAM, CF begins to grow, and the resistance of the path between top and bottom electrodes is reduced. In this case, if the amplitude of the next step of the set voltage is increased, the current flowing through the path between top and bottom electrodes is increased so that the intensity of electric field applied to a portion of the filament in the path that has not yet grown is increased; as a consequence, the thickness of filament that newly grows under this set voltage step is relatively increased as compared to the last step. In this analogy, following this set process which uses a stepwise increased voltage, the shape of finally formed CF is substantially a cone shape tapering from bottom to top. That is, CF changes to 101 from 101a. CF102a, 102 and 102c indicated by solid lines are formed when the set excitation is a stepwise decreased voltage. For example, using the set operation method in which the voltage is stepwise decreased as shown in FIG. 9, after each stage of CF has grown, the voltage subsequently applied on the storage unit of ReRAM is decreased, thereby realizing the functions of controlling the current flowing through the path between upper and lower electrodes to be stable and adjusting the final growth shape of CF to be approximately even cylindrical shape. The control of the shape of CF will have a direct influence on the improvements on the performances of ReRAM in terms of endurance, data retention and high/low resistance value window R_{off}/Rₒₙ, etc.

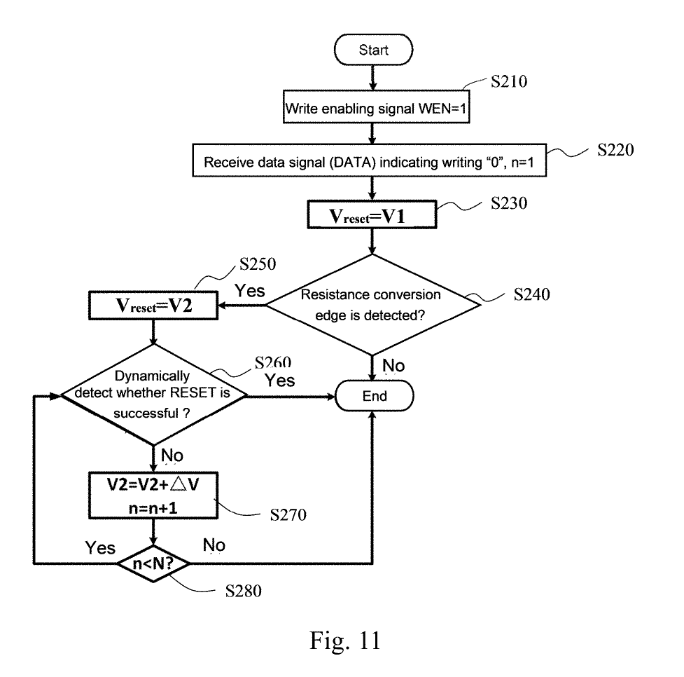

FIG. 11 is a schematic view of the flowchart of the method of reset operation according to an embodiment of the invention. The process of the reset operation will be described specifically based on the embodiments shown in FIGS. 11, 3 and 5.

Firstly, at step S210, the write enabling signal WEN is set at “1”, meaning that the write operation circuit is ready to initiate the write operation.

Next, at step S220, data signal (DATA) indicating writing DATA=0 is received, meaning that the reset operation is required to be performed at this point, and meanwhile, n is set at 1. At this point, the logic control module 340 enables the write operation signal generation module 350 to generate the reset operation signal 91 (including the pre-operation signal) as shown in FIG. 5 based on the DATA signal so as to exert excitation on the storage unit 371.

Next, at step S330, Vₛₑₜ=V1, that is, the pre-operation signal 91_{1′} of the reset operation signal 91 is applied to the storage unit 371, and the magnitude of the voltage of the pre-operation signal 91_{1′} is V1. At this step, DATA=0 simultaneously acts on the polarity selection module 360, and when DATA=0, the write operation voltage V_{write} is applied to the storage unit 371 in the SL direction. Of course, in case of unipolar write operation, the write operation voltage V_{write} is applied to the storage unit 371 in the BL direction.

Next, at step S240, whether an initiation of conversion from LRB to HRS is monitored. In an example, when the dynamically detected I_{write} is smaller than a certain predefined value Iᵣₑₛₑₜ₁ (Iᵣₑₛₑₜ₁ is larger than the current after the reset operation is successfully performed on the storage unit), it means that at this point, an initiation of resistance state conversion is happening in the storage unit 371, that is, a conversion from LRS to HRS begins, and the output signal FB1 is fed back. In another example, specifically, whether the resistance conversion edge is dynamically detected can be determined by an edge detection circuit. That is, as shown in FIG. 11, when the dynamically detected I_{write} is changed (I_{write} becomes somewhat smaller in the reset process), it means that an initiation of state conversion is happening in the storage unit 371, that is, a conversion from LRS to HRS begins, the edge detection circuit detects a descending edge of the voltage, and the output signal FB1 is fed back.

If an initiation of conversion from LRS to HRS is never monitored, it means that the storage unit has failed, and the reset process is ended.

Next, at step 250, V_{write}⁼V2, V2 is smaller than V1, that is, voltage V1 of the pre-operation signal 91_{1′} is decreased to voltage V2 of the pre-operation signal 91_{2′}, i.e., the initial voltage V2 of the conversion operation signal, and it is ready to form the stepwise increased conversion operation signal.

At step S260, whether the reset operation is successful is dynamically detected.

Specifically, when the dynamically detected I_{write} is smaller than a certain predefined value Iᵣₑₛₑₜ₂ (Iᵣₑₛₑₜ₂ is the current value in the write path after the operation on the storage unit is successful), it means that the reset operation is successfully performed on the storage unit 371, and the feedback signal FB2 is valid; thereby, the logic control module 340 controls the write operation signal generation module 350 to cut off the conversion operation signal of subsequent reset operation signal, and the reset operation signal is terminated, thus ending the reset process. If no I_{write} smaller than the certain predefined value Iᵣₑₛₑₜ₂ has been detected, the voltage of the reset operation signal is further decreased, that is, steps S270 and S280 are executed.

Next, at step S270, the reset signal is increased stepwise. For example, the pre-operation signal 91_{2′} is increased stepwise to form a signal 91_{3′}. The signal 91_{3′} is used to keep performing the reset operation process of conversion from LRS to HRS on the storage unit. The amplitude ΔV of stepwise increasing is not limiting, and can for example be 0.1V.

Next, N in step S280 represents the maximum times of stepwise increasing of the reset operation signal. If n≧N, then it may be difficult to successfully perform the reset operation on the storage unit, and the generation of reset operation signal is terminated, thus ending the reset operation process.

The above steps S260, S270 and S280 are executed repeatedly for several times so as to form the continuously stepwise increased conversion operation signal. The continuously stepwise increased conversion operation signal is biased on the storage unit 371 until the reset operation is successful, and the generation of reset operation signal is immediately terminated, thus avoiding excessive write excitation signals after the reset operation is successful. In this way, there will be no influence exerted by write excitation signal after the reset operation, which is advantageous for improving storage performance and reducing additional power consumption.

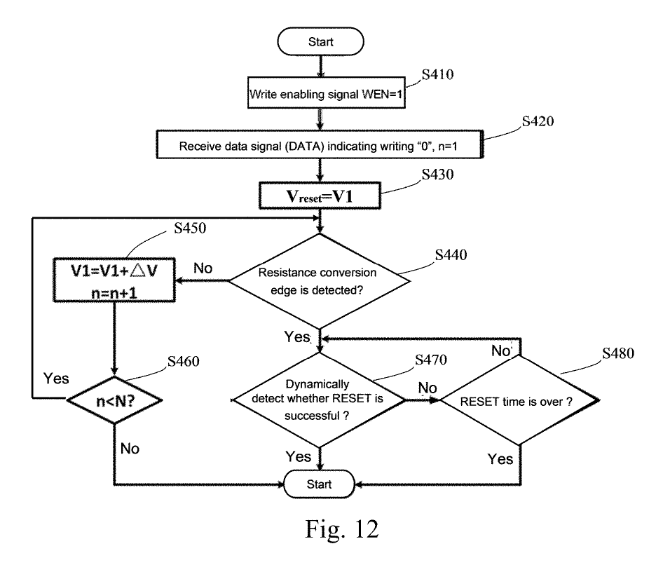

FIG. 12 is a schematic view of the flowchart of the method of reset operation according to another embodiment of the invention. The process of the reset operation will be described specifically based on the embodiments shown in FIGS. 12, 3 and 6.

Firstly, at step S410, the write enabling signal WEN is set at “1”, meaning that the write operation circuit is ready to initiate the write operation.

Next, at step S420, data signal (DATA) indicating writing DATA=0 is received, meaning that the reset operation is required to be performed at this point, and meanwhile, n is set at 1. At this point, the logic control module 340 enables the write operation signal generation module 350 to generate the reset operation signal 96 (including the pre-operation signal 96ᵣ) as shown in FIG. 5 based on the DATA signal so as to exert excitation on the storage unit 371.

Next, at step S430, Vₛₑₜ=V1, that is, the pre-operation signal 96_{1′} (the first voltage step of the stepwise increased pre-operation signal 96_{1′}) of the reset operation signal 96 is applied to the storage unit 371, and the magnitude of the initial voltage of the pre-operation signal 96_{1′} is V1. At this step, DATA=0 simultaneously acts on the polarity selection module 360, and when DATA=0, the write operation voltage V_{write} is applied to the storage unit 371 in the SL direction. Of course, in case of unipolar write operation, the write operation voltage V_{write} is applied to the storage unit 371 in the BL direction.

Next, at step S440, whether an initiation of conversion from LRB to HRS is monitored. In an example, when the dynamically detected I_{write} is smaller than a certain predefined value Iᵣₑₛₑₜ₁ (Iᵣₑₛₑₜ₁ is larger than the current after the reset operation is successfully performed on the storage unit), it means that at this point, an initiation of resistance state conversion is happening in the storage unit 371, that is, a conversion from LRS to HRS begins, and the output signal FB1 is fed back. In another example, specifically, whether the resistance conversion edge is dynamically detected can be determined by an edge detection circuit. That is, as shown in FIG. 11, when the dynamically detected I_{write} is changed (I_{write} becomes somewhat smaller in the reset process), it means that an initiation of state conversion is happening in the storage unit 371, that is, a conversion from LRS to HRS begins, the edge detection circuit detects a descending edge of the voltage, and the output signal FB1 is fed back.

If an initiation of conversion from LRS to HRS is not monitored in the time period in which the voltage of the pre-operation signal 96_{1′} equals to V1, the method proceeds to steps S450 and S460.

Next, at step S450, V1=V1+ΔV, i.e., the pre-operation signal 96_{1′} is increased stepwise, and in case of n<N (step S460), the method returns to step S440. In this way, steps S440, S450 and S460 can be executed repeatedly until it is determined “yes” at step S440. At step S460, if n≧N, it means that it may be difficult to successfully perform the reset operation on the storage unit, and the generation of reset operation signal is terminated, thus ending the reset operation process.

If it is determined “yes” at step S440, the method proceeds to step S470 to dynamically detect whether the reset operation is successfully. Specifically, the storage unit 371 is biased with a conversion operation signal having a constant voltage, and the voltage is equal to the maximum voltage of the pre-operation signal 96_{1′}. When the dynamically detected I_{write} is smaller than a certain predefined value Iᵣₑₛₑₜ₂ (Iᵣₑₛₑₜ₂ is the current value in the write path after the operation on the storage unit is successful), it means that the reset operation is successfully performed on the storage unit 371, and the feedback signal FB2 is valid; thereby, the logic control module 340 controls the write operation signal generation module 350 to cut off the subsequent conversion operation signal, and the reset operation signal is terminated, thus ending the reset process. Therefore, in this process, the conversion operation signal of the reset operation signal may be cut off at any moment. If no I_{write} smaller than the certain predefined value Iᵣₑₛₑₜ₂ has been detected, the method proceeds to step S480 to determine whether the time of reset operation has ended. If the time of reset operation is longer than a predetermined time, it means that the reset operation cannot be successfully performed on the storage unit and the reset operation is terminated; if it is determined “no”, it reset operation signal continues to be biased, and the method returns to step S470 until the reset operation is successful.

In the write operation methods and ReRAM for implementing the write operation methods of the above described embodiments, whether an initiation of conversion from HRS/LRS to LRS/HRS has happened is monitored under the bias of the pre-operation signal so as to control the variation of conversion operation signal in advance, i.e., to change the way how set/reset operation is performed in advance. In this way, the shape of conductive filaments in the storage medium of storage unit can be optimized, and the damage to the storage performance of the storage unit of ReRAM caused by the write operation can be reduced, thus improving the performance of the memory. For example, the storage performance of ReRAM can be improved in terms of consistency of resistance value in high resistance state and/or low resistance state, high resistance value/low resistance value window R_{off}/Rₒₙ, data retention, etc.

It should be understood that in the ReRAM of the invention, both a unipolar set/reset operation and a bipolar set/reset operation can be performed.

It is noted that in each of the above described stepwise varied signals, all of the amplitude, width, total step number of each step of voltage are adjustable, and they can be adjusted according to an actual statistical result of electrical parameters tested for a batch of memories.

It will be understood that when a component is referred to as being “connected” or “coupled” to another component, it can be directly connected to or coupled to said another component, or there can be an intervening component.

The above examples mainly describe the ReRAM of the invention and write operation methods thereof. While only some of the embodiments of the invention have been described, those skilled in the art will understand that the invention can be carried out in many other forms without departing from the spirit and scope thereof. For example, the increase and decrease of voltage can be realized in a linear manner, or a stepwise variation can be realized through discontinuous voltage pulses. Therefore, the illustrated examples and embodiments should be considered as illustrative rather than limiting, and the invention can cover various modifications and replacements without departing from the spirit and scope of the invention defined by individual appended claims.

1. A resistive random access memory, comprising:
a write operation signal generation module for at least generating a pre-operation signal of a set/reset operation signal and a conversion operation signal whose voltage is decreased/increased gradually; and
a conversion initiation monitoring module for determining whether an initiation of a conversion from a high resistance state/low resistance state to the low resistance state/high resistance state has happened in a storage unit of the resistive random access memory biased with the pre-operation signal, and outputting a first feedback signal (FB1) when the initiation of a conversion from a high resistance state/low resistance state to the low resistance state/high resistance state has happened;
wherein the write operation signal generation module generates the conversion operation signal based on the first feedback signal (FB1) and biases the conversion operation signal onto the storage unit so as to keep performing a set/reset operation process from the high resistance state/low resistance state to the low resistance state/high resistance state.

2. The resistive random access memory according to claim 1, wherein the conversion initiation monitoring module is further configured to monitor whether the set/reset operation is successful, and to output a second feedback signal (FB2) when a successful set/reset operation is monitored; and
wherein the write operation signal generation module stops generating the conversion operation signal based on the second feedback signal (FB2).

3. The resistive random access memory according to claim 1, wherein the conversion initiation monitoring module comprises:
a write path current detector for dynamically detecting a write current (I_{write}) in the write path when the set/reset operation signal is biased onto the selected storage unit; and
an edge detection circuit for at least monitoring the initiation of conversion from the high resistance state/low resistance state to the low resistance state/high resistance state and outputting the first feedback signal (FB1);
wherein the write path current detector outputs a voltage signal (V_{detect}) detected in the write path when the set/reset operation signal is biased onto the selected storage unit based on the write current (I_{write}), and the detected voltage signal (V_{detect}) is input to the edge detection circuit.

4. The resistive random access memory according to claim 3, wherein the edge detection circuit comprises a differentiating circuit and a first comparator.

5. The resistive random access memory according to claim 3, wherein the edge detection circuit is further used to monitor whether the set/reset operation is successful, and outputs the second feedback signal (FB2) when a successful set/reset operation is monitored.

6. The resistive random access memory according to claim 1, wherein the conversion initiation monitoring module comprises:
a write path current detector for dynamically detecting a write current (I_{write}) in the write path when a set/reset operation signal is biased onto the selected storage unit; and
a second comparator;
wherein the write path current detector outputs a voltage signal (V_{detect}) detected in the write path when the set/reset operation signal is biased onto the selected storage unit based on the write current (I_{write}), and the detected voltage signal (V_{detect}) is input to the second comparator; the second comparator compares the detected voltage signal (V_{detect}) with a first predefined value (Iₛₑₜ₁/Iᵣₑₛₑₜ₁), and when the detected voltage signal (V_{detect}) is larger/smaller than the first predefined value (Iₛₑₜ₁/Iᵣₑₛₑₜ₁), it means that an initiation of conversion from the high resistance state/low resistance state to the low resistance state/high resistance state has happened, and the second comparator outputs the first feedback signal (FB1).

7. The resistive random access memory according to claim 6, wherein the second comparator is configured to compare the detected voltage signal (V_{detect}) with a second predefined value (Iₛₑₜ₂/Iᵣₑₛₑₜ₂), and when the detected voltage signal (V_{detect}) is larger/smaller than the second predefined value (Iₛₑₜ₂/Iᵣₑₛₑₜ₂), it means that the set/reset operation is successful and the second comparator outputs the second feedback signal (FB2).

8. The resistive random access memory according to claim 1, wherein the voltage value of the pre-operation signal is constant, or the voltage value is increased gradually.

9. The resistive random access memory according to claim 8, wherein the maximum voltage value of the pre-operation signal is smaller than the set voltage/reset voltage of the storage unit.

10. The resistive random access memory according to claim 1, wherein the conversion operation signal whose voltage is decreased/increased gradually is a continuously stepwise decreased/increased conversion operation signal.

11. The resistive random access memory according to claim 10, wherein in the set operation, the conversion operation signal is continuously stepwise decreased from the pre-operation signal.

12. The resistive random access memory according to claim 10, wherein in the reset operation, the conversion operation signal is decreased to an initial step voltage from the pre-operation signal, and is then continuously stepwise increased.

13. A write operation method of resistive random access memory, comprising the following steps during a set/reset operation process:
biasing a pre-operation signal of a set/reset operation signal onto a storage unit of the resistive random access memory;
determining whether an initiation of a conversion from a high resistance state/low resistance state to the low resistance state/high resistance state has happened, and outputting a first feedback signal (FB1) if it is determined “yes”; and
generating a conversion operation signal whose voltage is decreased/increased gradually based on the first feedback signal (FB1), and biasing the conversion operation signal onto the storage unit so as to keep performing a set/reset operation process from the high resistance state/low resistance state to the low resistance state/high resistance state.

14. The write operation method according claim 13, wherein in the process of keep performing the set/reset operation, it is determined whether the set/reset operation is successful, and a second feedback signal (FB2) is output when it is determined that the set/reset operation is successful so as to terminate the set/reset operation.

15. The write operation method according claim 13, wherein in the process of determining whether an initiation of conversion from a high resistance state/low resistance state to the low resistance state/high resistance state has happened:
a write current (I_{write}) in the write path when a set/reset operation signal is biased onto the selected storage unit is dynamically detected; and
a voltage signal (V_{detect}) in the write path when the set/reset operation signal is biased onto the selected storage unit based on the write current (I_{write}) is detected, and the first feedback signal (FB1) is output based on a variation of the detected voltage signal (V_{detect}).

16. The write operation method according claim 15, wherein in the process of keep performing the set/reset operation, it is determined whether the set/reset operation is successful based on an ascending/descending edge of the detected voltage signal (V_{detect}), and outputting a second feedback signal (FB2) when it is determined that the set/reset operation is successful so as to terminate the set/reset operation.

17. The write operation method according claim 13, wherein in the process of determining whether an initiation of conversion from a high resistance state/low resistance state to the low resistance state/high resistance state has happened:
a write current (I_{write}) in the write path when a set/reset operation signal is biased onto the selected storage unit is dynamically detected;
a voltage signal (V_{detect}) in the write path when the set/reset operation signal is biased onto the selected storage unit based on the write current (I_{write}) is detected; and
the detected voltage signal (V_{detect}) is compared with a first predefined value (Iₛₑₜ₁/Iᵣₑₛₑₜ₁), and when the detected voltage signal (V_{detect}) is larger/smaller than the first predefined value (Iₛₑₜ₁/Iᵣₑₛₑₜ₁) it means that an initiation of conversion from the high resistance state/low resistance state to the low resistance state/high resistance state has happened.

18. The write operation method according claim 17, wherein in the process of keep performing the set/reset operation, the detected voltage signal (V_{detect}) is compared with a second predefined value (Iₛₑₜ₂/Iᵣₑₛₑₜ₂), and when the detected voltage signal (V_{detect}) is larger/smaller than the first predefined value (Iₛₑₜ₂/Iᵣₑₛₑₜ₂), it means the set/reset operation is successful and the second feedback signal (FB2) is output so as to terminate the set/reset operation.

19. The write operation method according claim 13, wherein the voltage value of the pre-operation signal is constant, or the voltage value is increased gradually.

20. The write operation method according claim 19, wherein the maximum voltage value of the pre-operation signal is smaller than the set voltage/reset voltage of the storage unit.

21. The write operation method according claim 13, wherein the conversion operation signal whose voltage is decreased/increased gradually is a continuously stepwise decreased/increased conversion operation signal.

22. The write operation method according claim 21, wherein in the set operation, the conversion operation signal is continuously stepwise decreased from the pre-operation signal.

23. The write operation method according claim 21, wherein in the reset operation, the conversion operation signal is decreased to an initial step voltage from the pre-operation signal, and is then continuously stepwise increased.

24. A resistive random access memory, comprising:
a write operation signal generation module which is used for at least generating a pre-operation signal whose voltage is increased gradually of a reset operation signal, and a conversion operation signal of the reset operation signal; and
a conversion initiation monitoring module for determining whether an initiation of a conversion from a low resistance state to a high resistance state has happened in a storage unit of the resistive random access memory biased with the pre-operation signal, and outputting a first feedback signal when the initiation of a conversion from a low resistance state to the high resistance state has happened;
wherein the write operation signal generation module terminates an increasing process of the pre-operation signal based on the first feedback signal and substantially maintains the output electrical level so as to generate the conversion operation signal, and biases the conversion operation signal onto the storage unit so as to keep performing the reset operation process from the low resistance state to the high resistance state.

25. The resistive random access memory according to claim 24, wherein the conversion initiation monitoring module is further configured to monitor whether the reset operation is successful, and to output a second feedback signal (FB2) when a successful reset operation is monitored; and
the write operation signal generation module stops generating the conversion operation signal based on the second feedback signal (FB2).

26. The resistive random access memory according to claim 24, wherein the conversion initiation monitoring module comprises:
a write path current detector for dynamically detecting a write current (I_{write}) in the write path when a reset operation signal is biased onto the selected storage unit; and
an edge detection circuit for at least monitoring the initiation of conversion from low resistance state to high resistance state and outputting the first feedback signal (FB1);
wherein the write path current detector outputs a voltage signal (V_{detect}) detected in the write path when the reset operation signal is biased onto the selected storage unit based on the write current (I_{write}), and the detected voltage signal (V_{detect}) is input to the edge detection circuit.

27. The resistive random access memory according to claim 26, wherein the edge detection circuit comprises a differentiating circuit and a first comparator.

28. The resistive random access memory according to claim 26, wherein the edge detection circuit is further used to monitor whether the reset operation is successful, and outputs the second feedback signal (FB2) when a successful reset operation is monitored.

29. The resistive random access memory according to claim 24, wherein the conversion initiation monitoring module comprises:
a write path current detector for dynamically detecting a write current (I_{write}) in the write path when a reset operation signal is biased onto the selected storage unit; and
a second comparator;
wherein the write path current detector outputs a voltage signal (V_{detect}) detected in the write path when the reset operation signal is biased onto the selected storage unit based on the write current (I_{write}), and the detected voltage signal (V_{detect}) is input to the second comparator; the second comparator compares the detected voltage signal (V_{detect}) with a first predefined value (Iᵣₑₛₑₜ₁), and when the detected voltage signal (V_{detect}) is smaller than the first predefined value (Iᵣₑₛₑₜ₁), it means that an initiation of conversion from the low resistance state to the high resistance state has happened, and the second comparator outputs the first feedback signal (FB1).

30. The resistive random access memory according to claim 29, wherein the second comparator is configured to compare the detected voltage signal (V_{detect}) with a second predefined value (Iᵣₑₛₑₜ₂), and when the detected voltage signal (V_{detect}) is smaller than the second predefined value (Iᵣₑₛₑₜ₂), it means that the reset operation is successful and the second comparator outputs the second feedback signal (FB2).

31. The resistive random access memory according to claim 24, wherein the pre-operation signal is a continuously stepwise increased signal.

32. The resistive random access memory according to claim 31, wherein the maximum voltage value of the pre-operation signal is smaller than the reset voltage of the storage unit.

33. A write operation method of resistive random access memory, comprising the following steps during a reset operation process:
biasing a pre-operation signal of a reset operation signal onto a storage unit of the resistive random access memory, wherein the voltage of the pre-operation signal is increased gradually;
determining whether an initiation of a conversion from a low resistance state to a high resistance state has happened, and outputting a first feedback signal if it is determined “yes”; and
terminating an increasing process of the pre-operation signal based on the first feedback signal and substantially maintaining the output electrical level so as to generate the conversion operation signal, and biasing the conversion operation signal onto the storage unit so as to keep performing the reset operation process from the low resistance state to the high resistance state.

34. The write operation method according claim 33, wherein in the process of keep performing the reset operation, it is determined whether the reset operation is successful, and a second feedback signal (FB2) is output when it is determined that the reset operation is successful so as to terminate the reset operation.

35. The write operation method according claim 33, wherein in the process of determining whether an initiation of conversion from a low resistance state to a high resistance state has happened:
a write current (I_{write}) in the write path when a reset operation signal is biased onto the selected storage unit is dynamically detected; and
a voltage signal (V_{detect}) in the write path when the reset operation signal is biased onto the selected storage unit based on the write current (I_{write}) is detected, and the first feedback signal (FB1) is output based on a variation of the detected voltage signal (V_{detect}).

36. The write operation method according claim 35, wherein in the process of keep performing the reset operation, it is determined whether the reset operation is successful based on a descending edge of the detected voltage signal (V_{detect}), and outputting a second feedback signal (FB2) when it is determined that the reset operation is successful so as to terminate the reset operation.

37. The write operation method according claim 33, wherein in the process of determining whether an initiation of conversion from a low resistance state to a high resistance state has happened:
a write current (I_{write}) in the write path when a reset operation signal is biased onto the selected storage unit is dynamically detected;
a voltage signal (V_{detect}) in the write path when the reset operation signal is biased onto the selected storage unit based on the write current (I_{write}) is detected; and
the detected voltage signal (V_{detect}) is compared with a first predefined value (Iᵣₑₛₑₜ₁), and when the detected voltage signal (V_{detect}) is smaller than the first predefined value (Iᵣₑₛₑₜ₁), it means that an initiation of conversion from the low resistance state to the high resistance state has happened.

38. The write operation method according claim 37, wherein in the process of keep performing the reset operation, the detected voltage signal (V_{detect}) is compared with a second predefined value (Iᵣₑₛₑₜ₂), and when the detected voltage signal (V_{detect}) is smaller than the first predefined value (Iᵣₑₛₑₜ₂), it means the reset operation is successful and the second feedback signal (FB2) is output so as to terminate the reset operation.

39. The write operation method according claim 33, wherein the pre-operation signal is a continuously stepwise increased signal.

40. The write operation method according to claim 39, wherein the maximum voltage value of the pre-operation signal is smaller than the reset voltage of the storage unit.
